(19) United States
(12) Patent Application Publication
(10) Pub. No.: US 2016/0126327 A1
(43) Pub. Date: May 5, 2016

(54) METHOD OF MAKING A SPLIT GATE MEMORY CELL

(71) Applicant: FREESCALE SEMICONDUCTOR, INC., AUSTIN, TX (US)

(72) Inventors: WEIZE CHEN, PHOENIX, AZ (US); SUNG-TAEG KANG, AUSTIN, TX (US); PATRICE M. PARRIS, PHOENIX, AZ (US)

(21) Appl. No.: 14/526,654

(22) Filed: Oct. 29, 2014

(51) Int. Cl. H01L 29/423; H01L 29/40; H01L 29/792; H01L 21/3213; H01L 29/49; H01L 21/28; H01L 21/321

(52) U.S. Cl. CPC H01L 29/42344; H01L 21/28282; H01L 29/401; H01L 21/32105; H01L 21/3213; H01L 21/32139; H01L 29/4916; H01L 29/792

(57) ABSTRACT

A method includes forming a first dielectric layer over a memory region and a second dielectric layer over a logic region. A first polysilicon layer is formed over the first and second dielectric layers. An opening is formed in the first polysilicon layer in the memory region. A charge storage layer is formed over the first polysilicon layer and in the opening. A second polysilicon layer is formed over the charge storage layer including in the opening. The second polysilicon layer is etched to remove the second polysilicon layer from over the first polysilicon layer and to leave a portion of the second polysilicon layer in the opening. The first polysilicon layer is etched to form a first gate in the logic region and the second polysilicon layer is etched in the opening to define a control gate of a first NVM cell and a control gate of a second NVM cell.

### BACKGROUND

1. Field

This disclosure relates generally to semiconductor memories, and more specifically, to making non-volatile memories (NVMs) that have a split gate.

2. Related Art

Split gate non-volatile memories (NVM) have been found to provide much benefit for reliable operation. Difficulties in manufacturing, however, have arisen in processing such structures. The close proximity of two gates that are separated by a charge storage layer, which may comprise nanoclusters, is part of the issue. Further the integration of the NVM with logic transistors increases the number of process steps.

Thus, there is a need for improvement in the manufacturing of split gate NVMs.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of a semiconductor device at a stage in processing according to an embodiment.

FIG. 2 is a cross section of the semiconductor device of FIG. 1 at a subsequent step in processing.

FIG. 3 is a cross section of the semiconductor device of FIG. 2 at a subsequent step in processing.

FIG. 4 is a cross section of the semiconductor device of FIG. 3 at a subsequent step in processing.

FIG. 5 is a cross section of the semiconductor device of FIG. 4 at a subsequent step in processing.

FIG. 6 is a cross section of the semiconductor device of FIG. 5 at a subsequent step in processing.

FIG. 7 is a cross section of the semiconductor device of FIG. 6 at a subsequent step in processing.

FIG. 8 is a cross section of the semiconductor device of FIG. 7 at a subsequent step in processing.

FIG. 9 is a cross section of the semiconductor device of FIG. 8 at a subsequent step in processing.

FIG. 10 is a cross section of a semiconductor device of FIG. 7 at an intermediate stage in processing according to another embodiment.

FIG. 11 is a cross section of the semiconductor device of FIG. 10 at a subsequent step in processing.

FIG. 12 is a cross section of the semiconductor device of FIG. 11 at a subsequent step in processing.

FIG. 13 is a cross section of the semiconductor device of FIG. 12 at a subsequent step in processing.

### DETAILED DESCRIPTION

Embodiments of devices and methods disclosed herein take advantage of the conformal deposition of polycrystalline silicon and process technology with small feature size to create a relatively flat transistor gate surface for non-volatile memory (NVM) cells suitable for chemical-mechanical polishing or blanket etch back process. The gate for the NVM cells include a portion of second layer of polysilicon over a first layer of polysilicon that is completely removed to reduce the height of the NVM gate stack by 40% or more. As a result, many opportunities for simplifying the process flow with devices that include both logic and memory components arise including combining similar process steps, reducing the number of masking steps, and improving device performance.

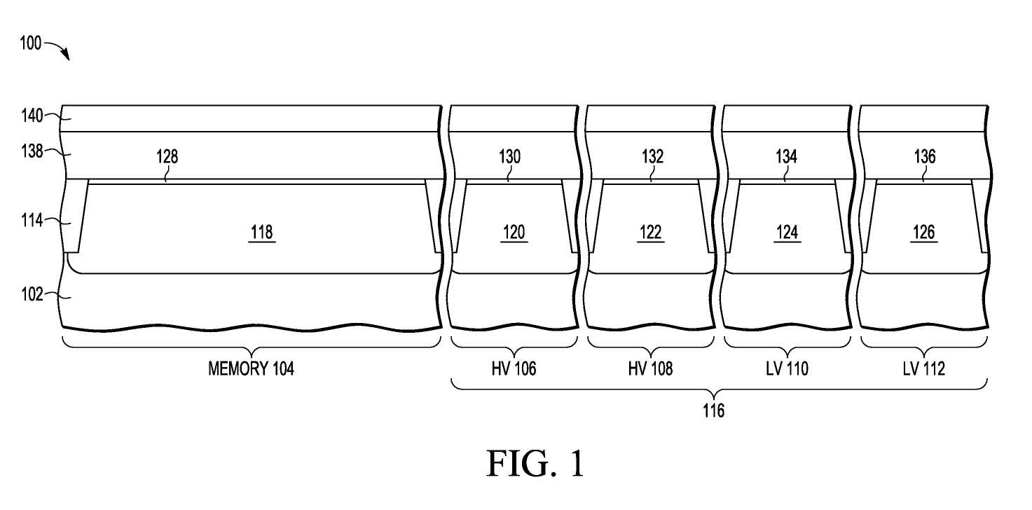

Shown in FIG. 1 is a semiconductor device 100 during an intermediate stage of manufacture comprising a semiconductor substrate 102 with isolation regions 114 separating each of memory region 104, high voltage regions 106, 108, and low voltage regions 110, 112. A respective one of doped wells 118, 120, 122, 124, 126 is formed in each of memory region 104, high voltage regions 106, 108, and low voltage regions 110, 112. Wells 118-126 can be implanted with either P-type or N-type doping depending on the type of devices to be formed in a particular region. For example, wells 118, 120 and 124 can be doped with P-type material while wells 122 and 126 can be doped with N-type material. Other suitable doping configurations for wells 118-126 can be used.

Gate dielectric layers 128, 130, 132, 134 and 136 are formed on substrate 102 in memory region 104, high voltage regions 106, 108, and low voltage regions 110, 112. Undoped polysilicon layer 138 is deposited on gate dielectric layers 128-136 and isolation regions 114, and an antireflective coating (ARC) 140 is deposited over polysilicon layer 138. ARC 140 can be a layer of nitride or other suitable material that functions as a hard mask.

Non-volatile memory (NVM) cells are to be formed in memory region 104. Logic and analog or power transistors are to be formed in high voltage regions 106, 108 and low voltage regions 110, 112, (collectively “logic region 116”). Logic transistors can perform any of a variety of logic functions.

Nitride layer 140 and polysilicon layer 138 may each be about 800 Angstroms thick. Other thicknesses may be used but ARC 140 can be at least 300 Angstroms thick for use as a hard mask and not just as an anti-reflective coating. Similarly, polysilicon layer 138 may be other thicknesses but can be at least 500 Angstroms thick. Gate dielectric layers 128-136 may be formed at the same time and thus be the same thickness which is beneficial if that is effective. If different gate dielectrics are needed they may be of a different material or different thickness. Gate dielectrics 128-136 may be thermally grown to about 40 Angstroms or other suitable thicknesses, for example, high voltage devices in high voltage regions 106, 108 may require thicker oxide than low voltage devices in low voltage regions 110, 112. A thin oxide layer (not shown), perhaps only 80 Angstroms thick, may be placed between polysilicon layer 138 and ARC 140.

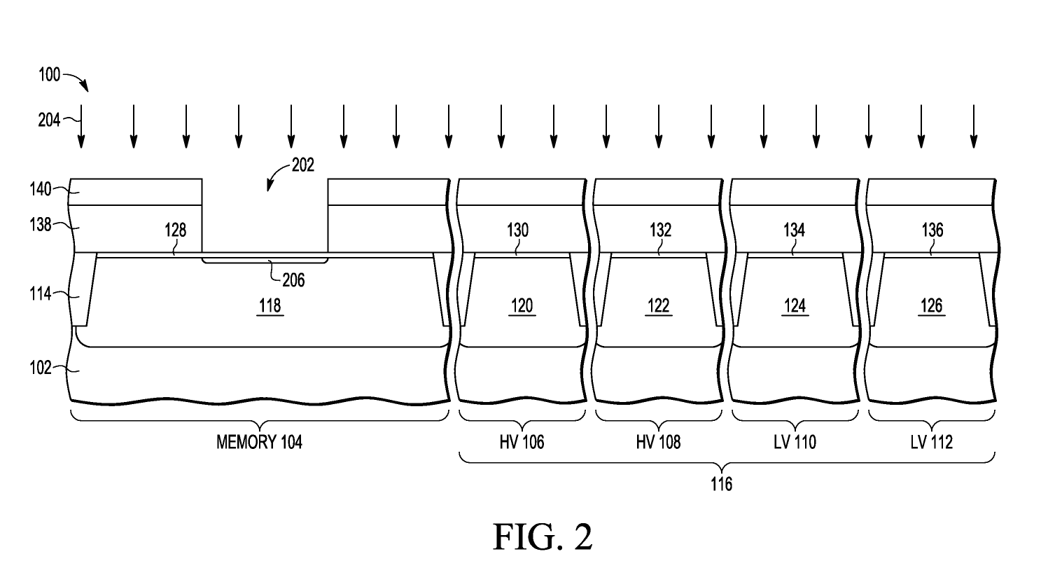

Shown in FIG. 2 is semiconductor device 100 after performing a patterned etch through ARC 140 and polysilicon layer 138 to form an opening 202. An anisotropic etch or other suitable etch process can be used. Logic region 116 and portions in memory region 104 on either side of opening 202 can be masked with photoresist or other protective material. Once opening 202 is formed, a portion of well 118 under opening 202 can optionally be counter-doped by implanting 204 a doping material of opposite conductive type as well 118.

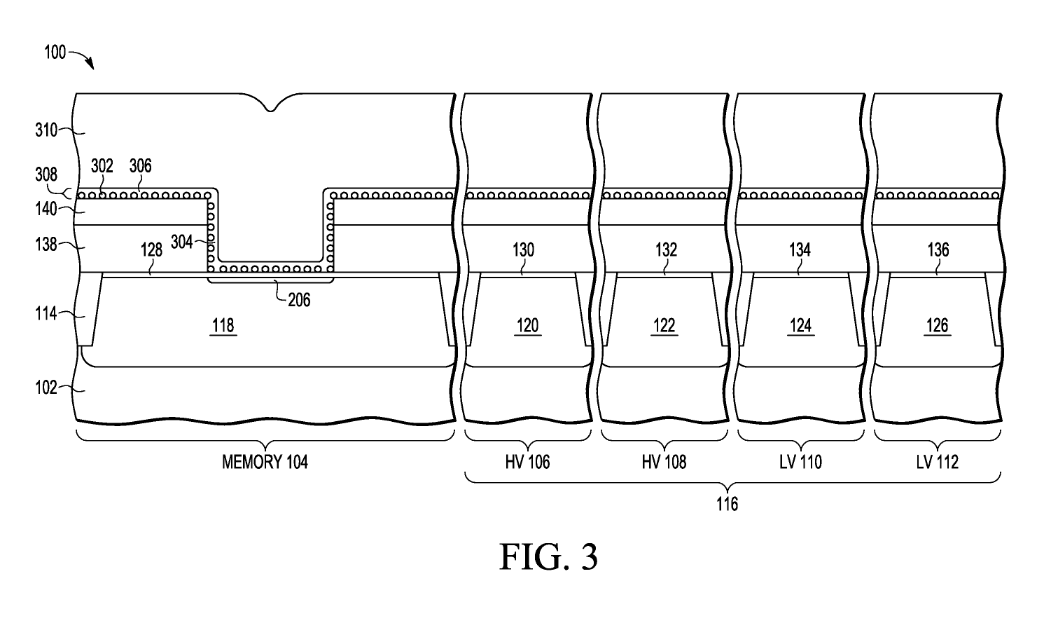

Shown in FIG. 3 is semiconductor device 100 after depositing a charge storage layer 308 including a bottom dielectric layer 302, charge storage element(s) 304, and top dielectric layer 306 over memory region 104 and logic region 116. Charge storage element(s) 304 may use nanoclusters of metal or crystalline material for discrete charge storage elements. Another charge material such as a layer of nitride may also be effective for charge storage layer 304.

Undoped polysilicon layer 310 is then conformally deposited over charge storage layer 308 in memory region 104 and logic region 116. The material of polysilicon layers 138 and 310 is useful in forming gates such as gates for use as control gates, gates for use as select gates, and gates for use as gates in transistors that perform logic functions as distinct from being an NVM. Other materials, such as metal or other conductive materials, may be used. Polysilicon layer 310 can be relatively thick, for example, at least as thick as the depth of opening 202 in FIG. 2.

Note that polysilicon layers 138, 310 may be doped instead of undoped material, however, subsequent sidewall oxidation may be more uniform using undoped polysilicon.

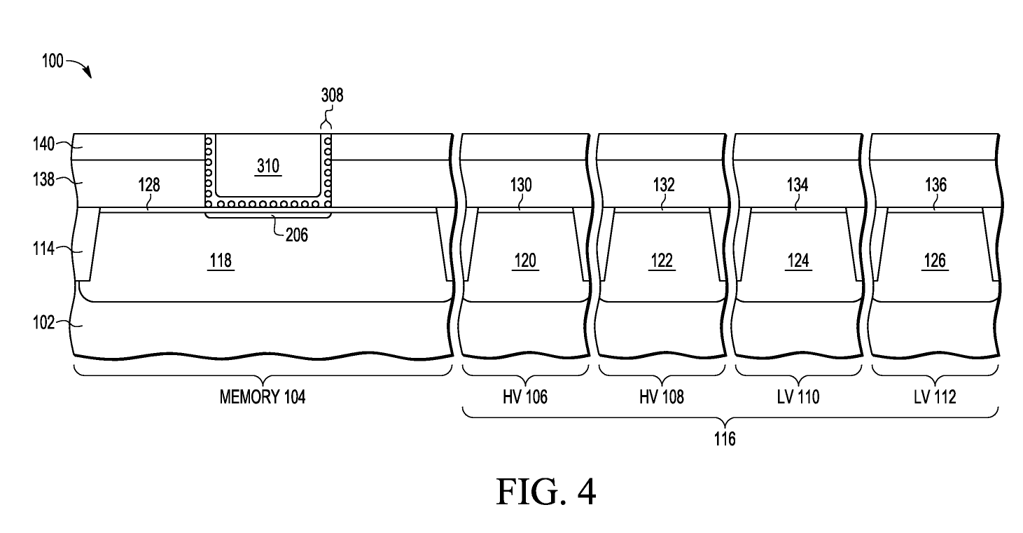

FIG. 4 is a cross section of the semiconductor device 100 of FIG. 3 at a subsequent step in processing after a patterned etch or CMP (Chemical Mechanical Polishing) is performed to remove unmasked portions of polysilicon layer 310 and charge storage layer 308 outside of opening 202 (FIG. 2) while masked portions of polysilicon layer 310 and charge storage layer 308 remain in opening 202. The etch back or CMP is performed using a chemistry that is selective between ARC 140 and polysilicon layer 310, with ARC 140 acting as an etch stop layer for the unmasked portion.

In other implementations, the etch chemistry may also be non-selective to oxide so that the top oxide layer 306 of charge storage layer 308 is not significantly etched. Such implementations would require an additional mask to remove an unmasked portion of charge storage layer 308 outside opening 202 after unmasked portions of polysilicon layer 310 are removed. Both polysilicon layer 310 and charge storage layer 308 in regions outside of opening 206 can also be removed by a masked or blanket etch or CMP.

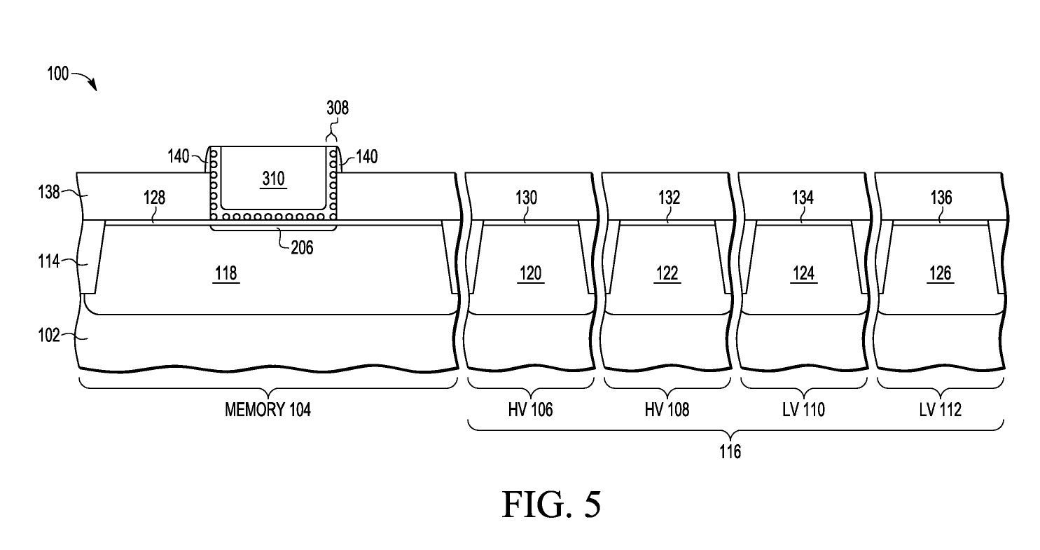

FIG. 5 is a cross section of the semiconductor device 100 of FIG. 4 at a subsequent step in processing in which ARC 140 is removed. A dry etch, or a wet etch of hot phosphoric acid, which is highly selective to oxide may be used to etch ARC 140. If a wet etch is used it may be desirable to have the thin oxide layer described earlier between polysilicon layer 138 and ARC 140 because hot phosphoric acid can pit polysilicon. Other suitable etch chemistries can be used, however. Note that residual portions of ARC 140 may remain along exposed sidewalls of charge store layer 308 after the etch process.

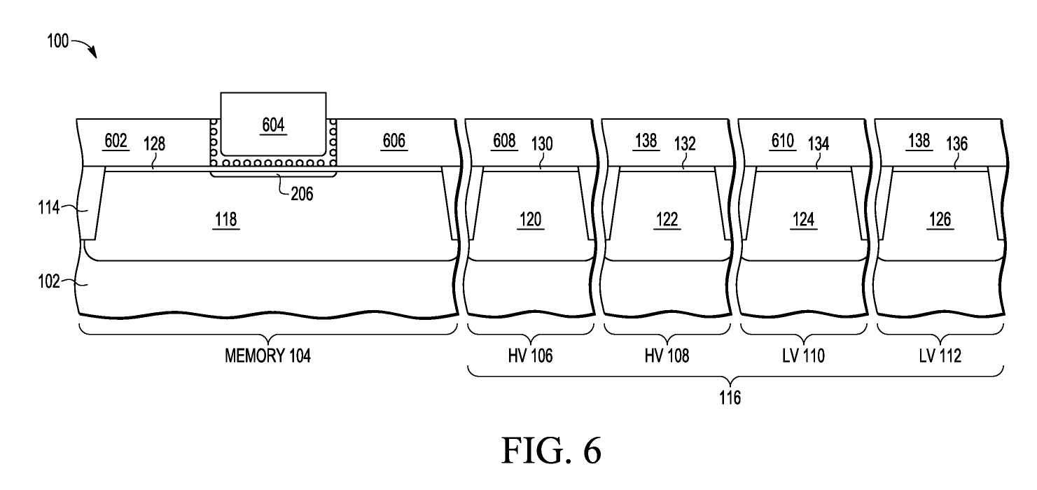

FIG. 6 is a cross section of the semiconductor device 100 of FIG. 5 at a subsequent step in processing in which selected sections of polysilicon layers 138, 310 are implanted with a doping material. Mask portions (not shown) are formed or deposited over high voltage region 108, low voltage region 112, and exposed portions of charge storage layer 308 during the implantation. Portions of undoped polysilicon layer 138 become respective doped polysilicon portions 602, 606 on either side of opening 202 in memory region 104, and doped polysilicon portions 608 and 610 in respective high voltage region 608 and low voltage region 610. A portion of undoped polysilicon layer 310 becomes doped polysilicon portion 604 in opening 202 in memory region 104. As an example, polysilicon portions 602, 604, 606, 608 and 610 can be doped with an N+ type material such as arsenic, phosphorous or other suitable N-type material. The conductivity type may be P-type in other embodiments,

Additionally, any exposed portion of charge storage layer 308 and residual portion of ARC 140 can be removed from the sidewalls of polysilicon portion 604. The removal can include etching or other suitable technique. Note that this step will not be necessary if the exposed portions of charge storage layer 308 has already been removed in a previous processing step, such as described for example with reference to FIG. 4.

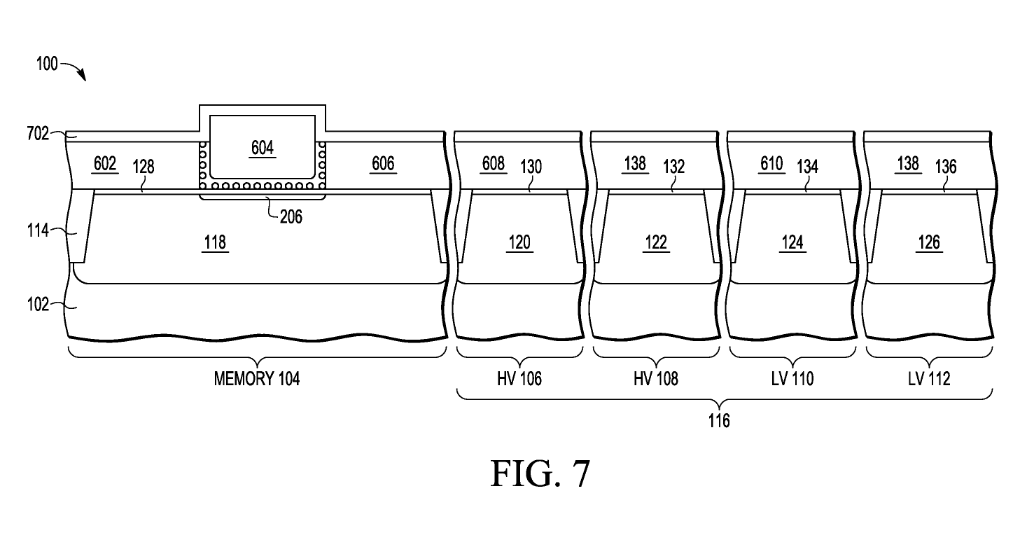

FIG. 7 is a cross section of the semiconductor device 100 of FIG. 6 at a subsequent step in processing in which antireflective coating (ARC) 702 is deposited over polysilicon portions 602-610 and remaining portions of polysilicon layer 138. ARC 702 can be a layer of nitride or other suitable material that functions as a hard mask. A thin oxide layer (not shown), perhaps only 80 Angstroms thick, may be placed between polysilicon portions 602-610 and remaining portions of polysilicon layer 138 and ARC 702.

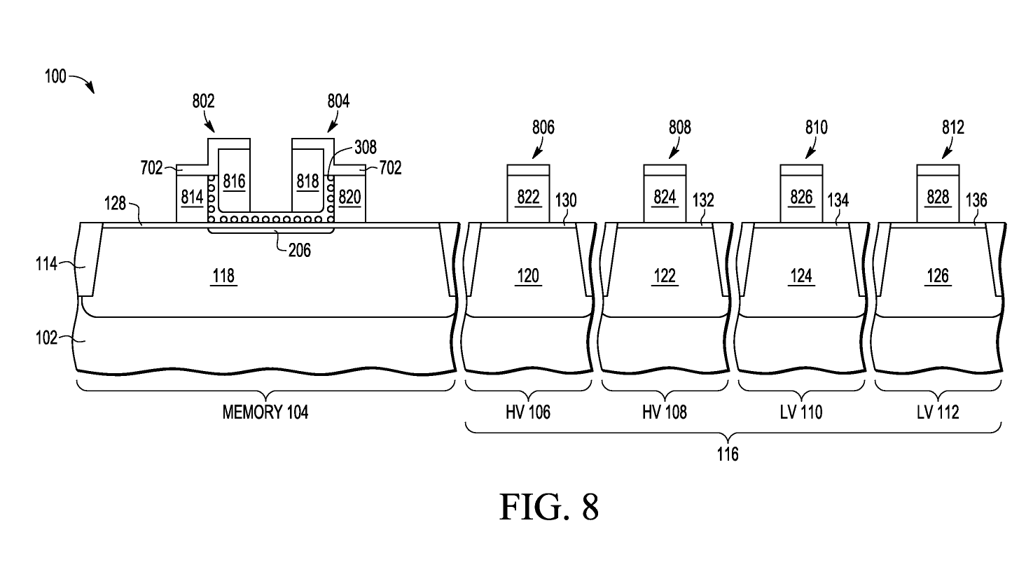

FIG. 8 is a cross section of the semiconductor device 100 of FIG. 7 at a subsequent step in processing in which a patterned etch is performed on ARC 702, polysilicon portions 602-610, and remaining portions of polysilicon layer 138 to form respective gate structures 802, 804, 806, 808, 810, 812 in memory region 104 and in high voltage regions 106, 108 and low voltage regions 110, 112. In memory region 104, gate structures 802, 804 include a respective select gate portion 814, 820 and control gate portion 816, 818.

Charge storage layer 308 remains between respective adjacent sidewalls of select gates 814, 820 and control gates 816, 818, between oxide layer 128 and the bottom of control gates 816, 818, and over oxide layer 128 between control gates 816, 818. Portions of ARC 702 remain on top of gate structures 802-812 after the patterned etch.

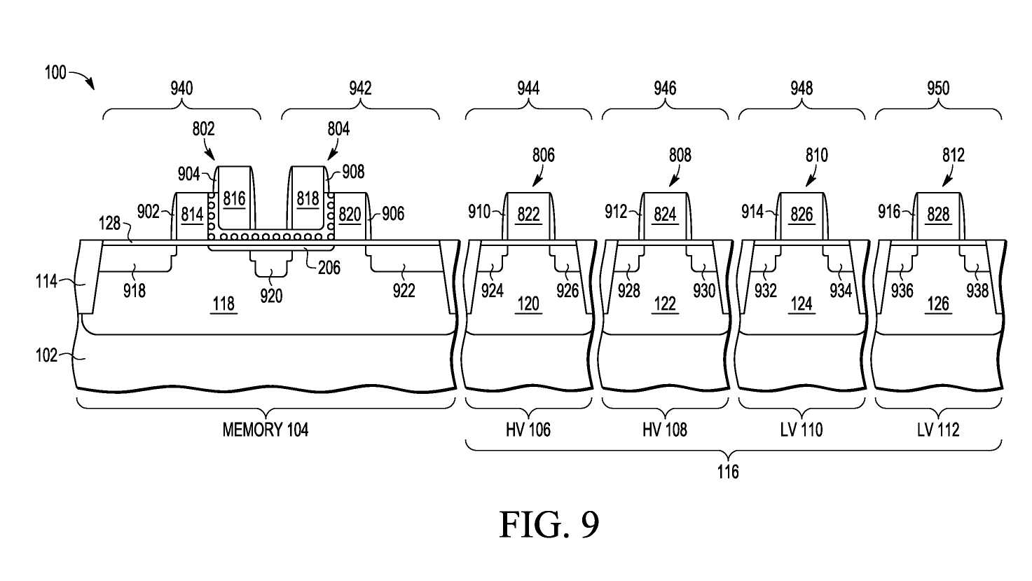

FIG. 9 is a cross section of the semiconductor device 100 of FIG. 8 at a subsequent step in processing in which the portion of charge storage layer 308 between control gates 816, 818 and ARC 702 is removed. In some embodiments, charge storage layer 308 and ARC 702 can be removed by etching. Other suitable techniques for removing charge storage layer 308 and ARC 702 can be used. Note that a residual portion 904, 908 of ARC 702 may remain on an upper portion of a sidewall of respective control gates 816, 818 above charge storage layer 308. The difference in height between control gates 816, 818 and select gates 814, 820 allows formation of a small section of spacer 902, 906 adjacent residual portions 904, 908 of ARC 702 provides electrical isolation and eliminates the need for another mask to silicide the exposed sidewall of control gates 816, 818.

In some embodiments, a mask layer for a halo implant that is part of source/drain implant region 920 can be used to etch charge storage layer 308 and ARC 702 between control gates 816, 818. The halo mask only opens up the area for the source halo implant between control gates 816, 818, which is the same area where charge storage layer 308 needs to be removed. So, device 100 can be patterned with a mask that exposes only the area between control gates 816, 818, the charge storage layer 308 can be removed while leaving the mask, the halo implant can be performed, and then mask can be removed.

After sidewall spacers 902-916 are formed, source/drain regions 918, 920, 922, 924, 926, 928, 930, 932, 934, 936, 938 may be implanted in adjacent gate structures 804-812 using sidewall spacers 902-916 and gates 814-820 as a mask. Extension regions of source/drain regions 918-938 may be implanted before respective spacers 902, 906, 910, 912, 914, 916 are formed. Additional processing may occur after source/drain regions 918-938 and spacers 902-916 are formed including siliciding source/drain regions 918-938 and gate structures 802-812, and forming contacts to source/drain regions 918-938 and gates 814-828.

The difference in height between control gates 816, 818 and select gates 814, 820 allows formation of a small section of spacer 902, 906 adjacent residual portions 904, 908 of ARC 702 in semiconductor device 100, providing electrical isolation and eliminating the need for another mask to silicide the exposed sidewall of control gates 816, 818 in device 100.

Memory cells 940, 942 in memory region 104 may be referred to as non-volatile memory cells and/or split gate non-volatile memory cells, and thus includes respective gate structures 802, 804 and source/drain regions 918-922. Logic transistors 944, 946, 948, 950 are formed in respective high voltage regions 106, 108 and low voltage regions 110, 112 with respective gate structures 822-828 and source/drain regions 924-938. Memory cells 940, 942 share a common doped source/drain region 920. Also, memory cells 940, 942 have their select gates 814, 818 and control gates 816, 820 defined with just one masking step. Further, gates 822-828 of transistors 944-950 are defined with the same masking step as the gates for memory cells 940, 942. Additionally, pre-doping implants are performed on select gates 814, 818, control gates 816, 820 and gate structures 822, 826 for transistors 944, 948 at the same time, eliminating yet another masking step.

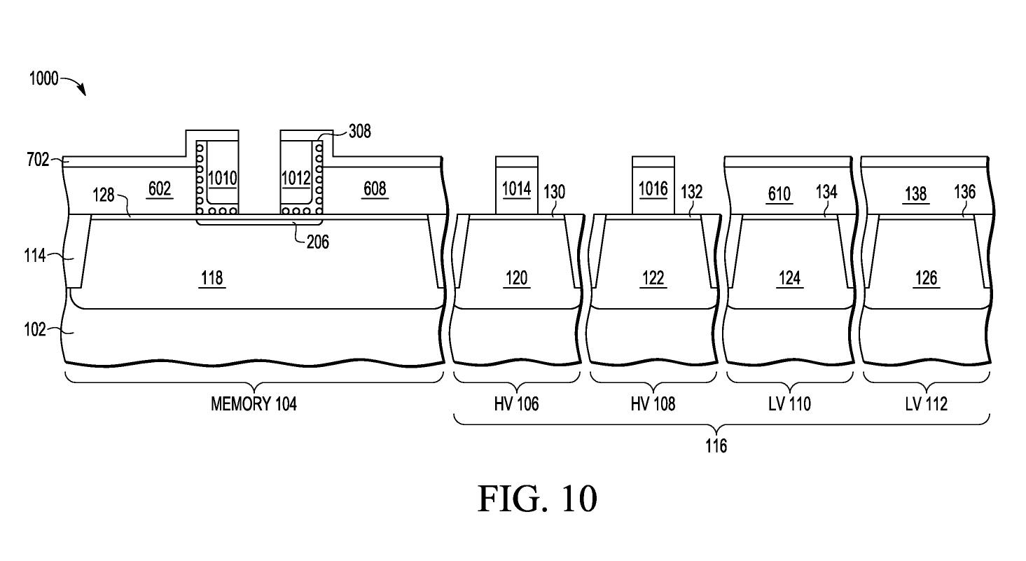

Given the requirement to remove the charge storage layer 308 from selected areas, such as the region between control gates 816 and 818 in FIG. 8, the embodiment shown in FIGS. 8 and 9 use an existing source halo implant mask as the etch mask for removing the charge storage layer 308 from between control gates 816 and 818. Certain process technologies may not require a halo implant mask, however, which means that an existing mask is not available to remove charge storage layer 308. Instead of adding a dedicated mask to remove charge storage layer 308 in such situations, an existing mask step can be used in another embodiment of semiconductor device 1000 of FIG. 10 to simultaneously define control gates 1010, 1012 in memory region 104, gates 1014, 1016 in high voltage regions 106, 108, to remove charge storage layer 308 between control gates 1010, 1012, and to reduce the thickness of exposed portions of insulating layers 130, 132 from high voltage regions 106, 108. Spacers 1102-1110 can optionally be formed in memory region 104 and high voltage regions 106, 108.

The etch process can also remove a majority of exposed portions of insulating layer 130, 132 in high voltage regions 106, 108. Insulating layer 130, 132 can be relatively thick, typically at around 150 Angstroms while charge storage layer 308 can be approximately 200-210 Angstroms thick. When charge storage layer 308 is removed between control gates 1010, 1012, at least some of insulating layers 130, 132 in high voltage regions 106, 108 will also be removed. The thickness of insulating layers 130, 132 provides protection against pitting into the underlying substrate 102 while charge storage layer 308 is removed between control gates 1010, 1012. At the same time the thickness of insulating layers 130, 132 is reduced during the etch process, subsequently allowing deeper doping implants in wells 120, 122. The deeper implants help achieve better breakdown voltage and lower leakage in subsequently formed transistors.

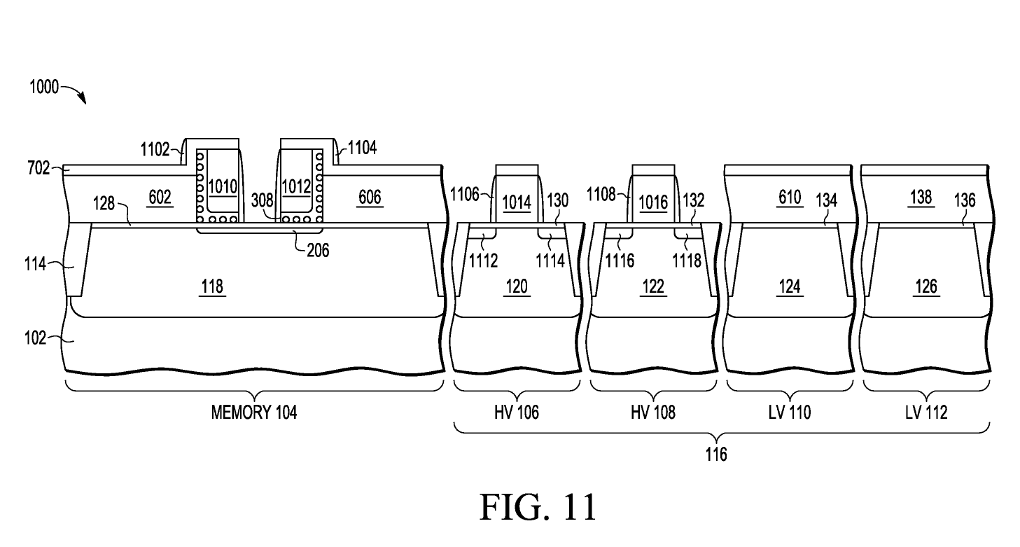

FIG. 11 is a cross section of the semiconductor device 1000 of FIG. 10 at a subsequent step in processing in which lightly doped drain (LDD) regions 1112, 1114, 1116, 1118 are formed in wells 120, 122. Spacers 1102, 1104 are then formed in a corner of ARC 702 proximate the junction of polysilicon portions 602, 606 and respective control gates 1010, 1012. Spacers 1106, 1108, 1110 are also formed on exposed sidewalls of gates 1014, 1016, and polysilicon portions 610 in respective high voltage and low voltage regions 106, 108, and 110. Spacers 1102-1110 can be relatively thin and can be used to improve breakdown voltage and leakage in subsequently formed transistors.

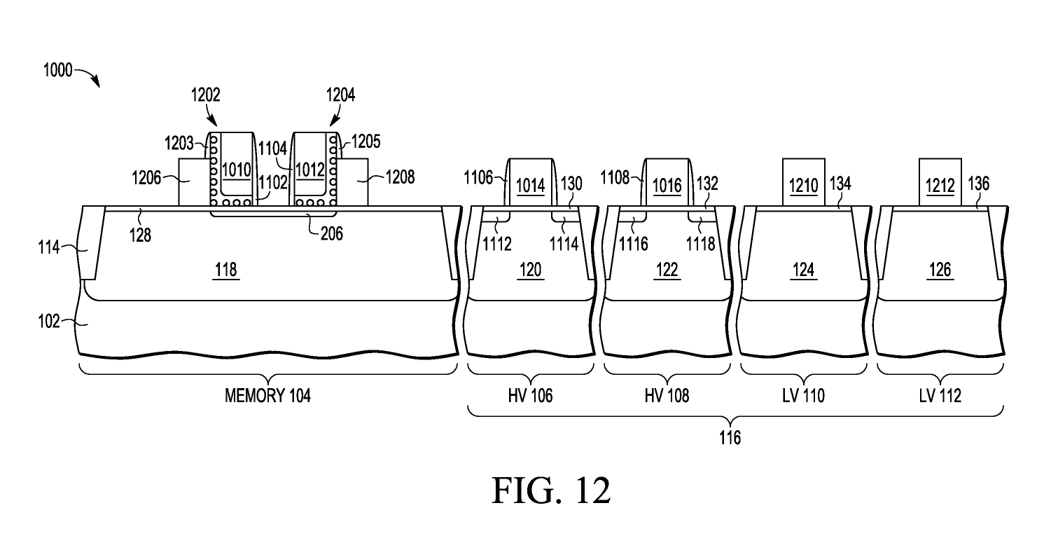

FIG. 12 is a cross section of the semiconductor device 1000 of FIG. 11 at a subsequent step in processing in which ARC 702 is removed in memory region 104 and logic region 116 and select gates 1206, 1208 are etched in memory region 104. Portions 1203, 1205 of the ARC may remain proximate the junction of select gates 1206, 1208 and respective control gates 1010, 1012. A patterned etch is performed to form select gates 1206, 1208 from polysilicon portions 602, 606 (FIG. 11), and logic transistor gates 1210, 1212 in respective low voltage regions 110, 112. The logic gate 1210 and 1212 can be etched in the same step that defines select gates 1206 and 1208 to minimize the number of masking and process steps.

During the patterned etch, an area extending from an outer sidewall of select gate 1206 to an outer sidewall of select gate 1208 can be masked. The mask area not only includes select gates 1206, 1208, but also control gates 1010, 1012, the opening between control gates 1010, 1012, and charge storage layer 308. Select gate 1206, control gate 1010, and a respective portion of charge storage layer 308 will be part of memory cell 1202. Control gate 1012, select gate 1208, and another respective portion of charge storage layer 308 will be part of memory cell 1204. Another portion of the mask can extend from a sidewall of spacer 1106 adjacent memory region 104 to the sidewall of spacer 1108 adjacent low voltage region 110. The areas over low voltage regions 110, 112 will remain unmasked when gates 124, 126 are defined or etched in the same step at select gates 126, 128. Spacers 1102, 1104, 1106 and 1108 therefore remain after the etch process while spacer 1110 (FIG. 11) may be removed during the etch process. Note that spacer 1110 may not necessarily be completely removed in some cases.

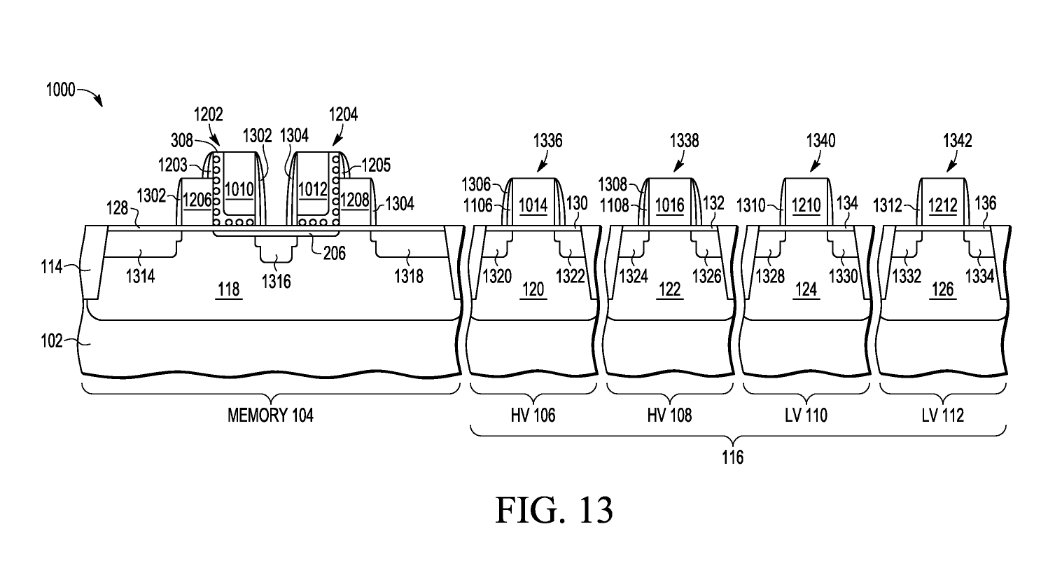

FIG. 13 is a cross section of the semiconductor device 1000 of FIG. 12 at a subsequent step in processing in which spacers 1302, 1304, 1306, 1308, 1310 and 1312 are formed around respective memory cells 1202, 1204, existing spacers 1106, 1108 and gates 1210, 1212. Source/drain regions 1314, 1316, 1318 are implanted adjacent respective select gate 1206, control gates 1010, 1012, and select gate 1208 in memory region 104 using sidewall spacers 1302, 1304 and gates 1206, 1010, 1012, 1208 as a mask to form memory cells 1202, 1204. Source/drain regions 1320, 1322, 1324, 1326, 1328, 1330, 1332, 1334 are implanted adjacent respective gates 1014, 1016, 1210, 1212 using sidewall spacers 1106/1306, 1108/1308, 1310 and 1312 and gates 1206, 1010, 1012, 1208 as a mask to form logic devices 1336, 1338, 1340, 1342 in logic region 116. Additional processing may occur after source/drain regions 1314-1334 and spacers 1302-1312 are formed including siliciding source/drain regions 1314-1334 and gates 1206, 1010, 1012, 1208, 1014, 1016, 1210, 1212, and forming contacts to source/drain regions 1314-1334 and gates 1206, 1010, 1012, 1208, 1014, 1016, 1210, 1212.

Defining gates 1014, 1016 in high voltage regions 106, 108 before defining gates in low voltage regions 110, 112 in a subsequent etch also allows additional sidewall spacers 1203, 1205, 1106, 1108 to be included in memory region 104 and high voltage regions 106, 108 without affecting low voltage regions 110, 112.

The embodiment of semiconductor device 1000 provides the opportunity to thin down insulating layers 130, 132 at the high voltage transistor source/drain region using the same process for removing charge storage layer 308 between memory cells 1202, 1204. This has the advantage of allowing the high voltage LDD implants in source/drain regions 1320-1326 to go deeper for better breakdown voltage and lower leakage current. It also allows for the source/drain implant to go deeper in the HV source/drain regions 1320-1326. Typically, the source/drain implants are shared among all the MOSFETs of the same type including low voltage, dual gate oxide, high voltage, non-volatile memory, etc. The implant conditions are usually optimized for low voltage devices, which have a very thin gate oxide compared to the high voltage gate oxide, and their implant energies might not be adequate or optimized if a thick high voltage gate oxide is still in place. In addition, prior to silicidation of the source/drain region 1320-1326, a wet clean is used to completely remove the remaining gate oxide from the source/drain area to ensure the deposited metal is in direct contact with the underlying substrate 102. With the thick high voltage gate oxide still in the source/drain area of the high voltage devices, a longer wet clean is needed to remove it, which may over-etch other areas, in particular the low voltage regions 110, 112, potentially causing too much of a recess to form in trench isolation regions 114, which can result in junction leakage. In addition, semiconductor device 1000 offers an opportunity to use additional sidewall spacer 1203, 1205, 1106, 1108 in memory region 104 and high voltage regions 106, 108, which will improve breakdown and leakage.

By now it should be appreciated that in some embodiments there has been provided a method, using a semiconductor substrate (102), of making a semiconductor structure (100) having a memory region (104) and a logic region (116) that can include forming a first dielectric layer (128) over the memory region (104); forming a second dielectric layer (130, 132, 134, 136) over a first portion (106-112) of the logic region; forming a first polysilicon layer (138) over the first dielectric layer and the second dielectric layer; forming an opening (202) in the first polysilicon layer in the memory region; forming a charge storage layer (308) over the first polysilicon layer and in the opening; forming a second polysilicon layer (310) over the charge storage layer (308) including in the opening; etching the second polysilicon layer (FIG. 4) to remove the second polysilicon layer from over the first polysilicon layer and to leave a portion of the second polysilicon layer in the opening; and etching the first polysilicon layer to form a first gate (806, 808, 810, 812, 1014, 1016) over the first portion of the logic region and etching the second polysilicon layer in the opening to define an edge of a control gate (816, 1010) of a first split gate non-volatile memory (NVM) cell (802, 1202) and an edge of a control gate (818, 1012) of a second split gate NVM cell (804, 1204).

In another aspect, the etching the first polysilicon layer and the second polysilicon layer can be further characterized by defining an edge (FIG. 8) of a select gate (814) of the first split gate (802) NVM cell and an edge of a select gate (820) of the second split gate NVM cell (804).

In another aspect, the method can further comprise etching the first polysilicon layer to form a second gate (1210, 1212) and define an edge of a select gate (1206) of the first split gate NVM cell (1202) and define and an edge of a select gate (1208) of the second split gate NVM cell (1204).

In another aspect, the etching the first polysilicon layer to form the second gate can be performed after the etching the second polysilicon layer.

In another aspect, the forming the opening can be further characterized by the opening extending to the substrate.

In another aspect, the forming the charge storage layer can comprise forming a bottom oxide (302) by thermal oxidation on sides of the first polysilicon layer of the opening and on the substrate at a bottom of the opening; and forming nanoclusters (304) on the bottom oxide.

In another aspect, the forming the second dielectric layer (130, 132) can be further characterized by the second dielectric layer being thicker than the first dielectric layer.

In another aspect, the method can further comprise forming a third dielectric layer (130, 132, 134) over a second portion of the logic region having a thickness different from the second dielectric layer prior to forming the first polysilicon layer. The forming a first polysilicon layer (138) can further characterized as forming the first polysilicon layer over the third dielectric layer. Etching the first polysilicon layer can further include etching the first polysilicon layer over the third dielectric layer to form a second gate (808, 810, 812).

In another aspect, the forming the first dielectric layer and the forming the third dielectric layer can be performed simultaneously.

In another aspect, the etching the first polysilicon layer to form the first gate can be further characterized by the first gate comprising one of a group consisting of a high voltage gate, a logic gate, and a dummy gate.

In another aspect, the method can further comprise forming a hard mask on the first polysilicon layer prior to the forming the opening in the first polysilicon layer.

In another aspect, the method can further comprise removing the hard mask after the etching and before the etching the first polysilicon layer.

In another aspect, the removing the hard mask can result in the portion of the second polysilicon layer having an extension above a top surface of the first polysilicon layer.

In another aspect, the method can further comprise removing the charge storage layer along a sidewall of the extension; and forming a conformal dielectric layer over the extension including the sidewall prior to the etching the first polysilicon layer and the second polysilicon layer.

In another aspect, the etching can comprise performing chemical mechanical polishing.

In another aspect, the etching can further comprise performing a patterned etch of the second polysilicon layer to leave a portion of the second polysilicon layer over the charge storage layer.

In another embodiment, a semiconductor structure (100, FIG. 8) having a substrate (102), can comprise a split gate NVM cell structure (802) in a memory portion (104) of the semiconductor device, a select gate structure having a first height above a major surface of the substrate, a control gate structure having a second height above a major surface of the substrate greater than the first height, a nanocluster layer between the control gate and the substrate, and a dielectric layer (702) over the select gate and above the nanocluster layer along a sidewall of the control gate. A portion of the sidewall of the control gate that is above the select gate is free from the nanocluster layer. A transistor gate structure (806-812) can be in a logic portion of the semiconductor device. The transistor gate structure has the first height.

In another aspect, the transistor gate structure can comprise one of a group consisting of a dummy gate, a logic gate, and a high voltage gate.

In a further embodiment, a method, using a semiconductor substrate (102), of making a semiconductor structure (100) having a memory region (104) and a logic region (116), can comprise forming a first polysilicon layer over the substrate in the memory region and the logic region; forming an opening in the first polysilicon layer in the memory region; forming a charge storage layer over the first polysilicon layer and in the opening; forming a polysilicon portion in the opening over the charge storage layer by depositing a second polysilicon layer and performing an etch back of the second polysilicon layer and the charge storage layer; and patterning the polysilicon portion to form a first control gate structure and a second control gate structure and the first polysilicon layer to form a first gate structure in the logic region.

In another aspect, the method can further comprise patterning the first polysilicon layer to form a first select gate structure adjacent to the first control gate structure, a second select gate structure adjacent to the second control gate structure, and a second gate structure in the logic region.

Although the invention is described herein with reference to specific embodiments, various modifications and changes can be made, some of which have been described previously, without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method, using a semiconductor substrate, of making a semiconductor structure having a memory region and a logic region, comprising:
forming a first dielectric layer over the memory region;
forming a second dielectric layer over a first portion of the logic region;
forming a first polysilicon layer over the first dielectric layer and the second dielectric layer;
depositing a hard mask layer over the first polysilicon layer
forming an opening in the first polysilicon layer and the hard mask layer in the memory region;
forming a charge storage layer over the hard mask first polysilicon layer and in the opening;
forming a second polysilicon layer over the charge storage layer including in the opening;
etching the second polysilicon layer to remove the second polysilicon layer from over the hard mask layer while leaving a portion of the second polysilicon layer in the opening, wherein the portion of the second polysilicon layer has a single height;
removing the hard mask layer over the first polysilicon layer while the portion of the second polysilicon layer remains at the single height; and
etching the first polysilicon layer to form a first gate over the first portion of the logic region and etching the second polysilicon layer in the opening to define an edge of a control gate of a first split gate non-volatile memory (NVM) cell and an edge of a control gate of a second split gate NVM cell while the portion of the second polysilicon layer remains at the single height.

2. The method of claim 1, wherein the etching the first polysilicon layer and the second polysilicon layer is further characterized by defining an edge of a select gate of the first split gate NVM cell and an edge of a select gate of the second split gate NVM cell.

3. The method of claim 1, further comprising etching the first polysilicon layer to form a second gate and define an edge of a select gate of the first split gate NVM cell and define an edge of a select gate of the second split gate NVM cell.

4. The method of claim 3, wherein the etching the first polysilicon layer to form the second gate is performed after the removing the second polysilicon layer from over the hard mask.

5. The method of claim 4, wherein the forming the opening is further characterized by the opening extending to the substrate.

6. The method of claim 5, wherein the forming the charge storage layer comprises:
forming a bottom oxide by thermal oxidation on sides of the first polysilicon layer of the opening and on the substrate at a bottom of the opening; and
forming nanoclusters on the bottom oxide.

7. The method of claim 1, wherein the forming the second dielectric layer is further characterized by the second dielectric layer being thicker than the first dielectric layer.

8. The method of claim 7, further comprising:
forming a third dielectric layer over a second portion of the logic region having a thickness different from the second dielectric layer prior to forming the first polysilicon layer,
wherein:
the forming a first polysilicon layer is further characterized as forming the first polysilicon layer over the third dielectric layer; and
the etching the first polysilicon layer further includes etching the first polysilicon layer over the third dielectric layer to form a second gate.

9. The method of claim 8, wherein the forming the first dielectric layer and the forming the third dielectric layer are performed simultaneously.

10. The method of claim 1, wherein the etching the first polysilicon layer to form the first gate is further characterized by the first gate comprising one of a group consisting of a high voltage gate, a logic gate, and a dummy gate.

11. The method of claim 1, wherein the hard mask layer is an anti-reflective coating layer.

12. (canceled)

13. The method of claim 1, wherein the removing the hard mask results in the portion of the second polysilicon layer having an extension adjacent to a top surface of the first polysilicon layer.

14. The method of claim 13, further comprising:
removing the charge storage layer along a sidewall of the extension; and
forming a conformal dielectric layer over the extension including the sidewall prior to the etching the first polysilicon layer and the second polysilicon layer.

15. The method of claim 1, wherein the etching comprises performing chemical mechanical polishing.

16. The method of claim 15, wherein the etching further comprises performing a patterned etch of the second polysilicon layer to leave a portion of the second polysilicon layer over the charge storage layer.

17. A semiconductor structure having a substrate, comprising:
a first split gate NVM cell structure and a second split gate NVM cell structure in a memory portion of the semiconductor device, each of the first and second split gate NVM cell structures comprising:
a select gate structure having a first height above a major surface of the substrate;
a control gate structure having a single second height above a major surface of the substrate greater than the first height;
a nanocluster layer between the control gate and the substrate; and
a dielectric layer over the select gate and above the nanocluster layer along a sidewall of the control gate,
wherein a portion of the sidewall of the control gate that is above the select gate is free from the nanocluster layer; and
a transistor gate structure in a logic portion of the semiconductor device, wherein the transistor gate structure has the first height.

18. The semiconductor structure of claim 17, wherein the transistor gate structure comprises one of a group consisting of a dummy gate, a logic gate, and a high voltage gate.

19. A method, using a semiconductor substrate, of making a semiconductor structure having a memory region and a logic region, comprising:
forming a first polysilicon layer over the substrate in the memory region and the logic region;
forming an opening in the first polysilicon layer in the memory region;
forming a charge storage layer over the first polysilicon layer and in the opening;
forming a polysilicon portion in the opening over the charge storage layer by depositing a second polysilicon layer and performing an etch back of the second polysilicon layer and the charge storage layer;
patterning the polysilicon portion to form a first control gate structure and a second control gate structure in the opening and the first polysilicon layer to form a first gate structure in the logic region, wherein the first and second control gate structures have a single height that is greater than a height of the first polysilicon layer.

20. The semiconductor device of claim 19, further comprising patterning the first polysilicon layer to form a first select gate structure adjacent to the first control gate structure, a second select gate structure adjacent to the second control gate structure, and a second gate structure in the logic region.
